(19) United States
(12) Patent Application Publication
(10) Pub. No.: US 2022/0077509 A1
(43) Pub. Date: Mar. 10, 2022

(54) METHOD FOR MONITORING AND CONTROLLING A BATTERY CELL UNIT

(71) Applicant: Robert Bosch GmbH, Stuttgart (DE)

(72) Inventors: Carlos Ziebert, Bretten (DE); Joachim Joos, Gerlingen (DE); Johannes Grabowski, Stuttgart (DE); Timo Herberholz, Stuttgart (DE)

(21) Appl. No.: 17/413,099

(22) PCT Filed: Sep. 26, 2019
(86) PCT No.: PCT/EP2019/076008

§ 371 Date: Jun. 11, 2021

(30) Foreign Application Priority Data
Dec. 14, 2018 (DE) 10 2018 221 813.7

(51) Int. Cl. H01M 10/42; H02J 7/00; H01M 10/48; H01M 10/44

(52) U.S. Cl. CPC H01M 10/425; H02J 7/007; H02J 7/0048; H01M 10/482; H01M 10/486; H01M 10/44; H02J 7/0013

(57) ABSTRACT

The present invention relates to a method for monitoring and controlling a battery cell unit. The invention also relates to a battery cell unit, a battery system and to a use of the claimed method for monitoring and controlling the battery system.

### BACKGROUND OF THE INVENTION

The present invention relates to a method for monitoring and controlling a battery cell unit. In addition, the invention relates to a battery cell unit, to a battery system, and to a use of the method for monitoring and controlling the battery system.

Battery cells, in particular secondary cells, change their properties over their life. When used in mobile applications, in particular vehicles, it may arise that the life of the battery cells is less than that of the vehicle. When using a plurality of cells, it may arise that not all of the cells age uniformly, but at a different rate. This often results in an entire battery system needing to be replaced on failure of a single cell. During monitoring and control of the battery cells, it would therefore be advantageous if a measurable variable could be used as parameter which particularly accurately reflects the state of the battery cell.

### SUMMARY OF THE INVENTION

The subject of the invention is a method and a battery cell unit, a battery system , and a use of the method.

Protection is particularly provided for a method for monitoring and controlling a battery cell unit, which has the following steps:
At least one battery cell, which has a first terminal, which is connected to an input, which is connectable to a first electrical element, and has a second terminal, which is connected to an output, which is connectable to a second electrical element, is provided. Likewise, a switch is provided, which is suitable for connecting the first terminal to the input or disconnecting this connection.
A further step represents the opening of the first switch, for disconnecting the connection between the input and the first terminal.
In a further step, a measured variable of the battery cell disconnected from the input is determined. The determined measured variable is evaluated, wherein at least one switching value is determined on the basis of the measured variable. Likewise, the switching state of the first switch is adapted on the basis of the at least one switching value. In this case, the abovementioned steps are used for controlling and monitoring the battery cell unit.

In other words, an energy store in the form of a battery cell, in particular a secondary cell, having a positive terminal and a negative terminal is provided. Since, in connection with the invention, the physical processes of current conduction are not of interest, the terms positive and negative are interchangeable. The input is connectable to a first electrical element, wherein this first electrical element may be, for example, a further battery cell unit, an electrical circuit, a consumer or a connecting element, in particular in the form of a male connector or a female connector. The second electrical element, which is connectable to the output, can also have at least the just-mentioned electrical elements.

Instead of a single battery cell, it is also possible for a plurality of battery cells, in particular two battery cells, to be arranged within a battery cell unit, wherein said battery cells can be connected both in parallel and in series. In this case, in the case of a series circuit, in each case only one battery cell is connected to the input and a further battery cell is connected to the output, and, in the case of a parallel circuit, if appropriate, a plurality of battery cells is connected to the input and to the output. The use of a plurality of battery cells provides the advantage that the voltage or the current can be increased.

Furthermore, a first switch is provided, which, in the closed state, connects the first terminal of the battery cell to the input and, in the open state, disconnects this connection. In this case, the connection between the input and the first terminal of the battery cell can take place directly via the switch and via one or more cell lines. In this case, the switch itself can be in the form of a relay, for example, which provides the advantage of DC isolation which is particularly safe. As an alternative, provision can also be made for the switch to be based on a semiconductor, as a result of which a high number of switching cycles can be enabled. Likewise, the switch can also be in the form of a MOSFET or IGFET, which can be designed to be particularly small and favorable.

By virtue of the opening of the switch, the at least one battery cell, in particular two or more battery cells, is disconnected from the input. As a result, the at least one battery cell, in particular two or more battery cells, can no longer output any current to the first electrical element and/or the second electrical element. Charging of the battery cell in this state is also not possible.

The opening of the first switch can take place at specific intervals, which are adapted in particular to the measured variable to be determined.

The measured variable which is determined by the battery cell disconnected from the input may be any measurable variable, in particular temperature, pressure, concentration or electrical variables, such as, for example, voltage, current, or impedance. The measured variables can be detected by measurement means, wherein corresponding accesses to the battery cell unit are provided. In order to measure electrical variables, further terminals can be provided at the at least one battery cell, in particular at a plurality of battery cells. Thus, for example, a means for measuring the impedance can be connected to at least one or in particular a plurality of battery cells in order to measure the impedance at the time at which the first switch is open and the battery cell or battery cells are deenergized. This provides the advantage that, in this way, the impedance can be determined with particular accuracy, which enables improved description of the state of the cell.

During the evaluation of the measured variable, a switching value is determined on the basis of the measured variable. In this case, the switching value can have a logic value which can act as setpoint value for a switch. For example, a switching value of 1 would correspond to a closed switch, and a switching value of 0 would correspond to an open switch. During the evaluation of the measured variable, the measured variable can be compared with a setpoint value or setpoint range. This setpoint value may be, for example, a universally valid setpoint value, for example a cell voltage, which should not be undershot. This provides the advantage that, irrespective of the state differences of the battery cells which may be present, switching values of the first switch can be determined. As an alternative to this or in addition, it is also possible for the measured variable to be compared with a setpoint value, which has been individually adapted to the battery cell. Thus, it may arise, for example, that battery cells are subject to certain manufacturing-dependent fluctuations. Thus, for example, a cell which has a low voltage from the beginning of production on, but, for this, has an increased capacity, for example, can obtain a correspondingly adapted setpoint value.

For the evaluation, an evaluation unit can be provided, which may be in the form of a microcontroller, in particular. Microcontrollers provide the advantage that they can be designed to be particularly small and favorable. Furthermore, provision can be made for the evaluation unit to be in the form of an FPGA, which can be adapted particularly easily to measurement tasks. As an alternative or in addition to this, the evaluation unit can also be in the form of an ASIC, which can be produced particularly favorably in large production numbers.

The determined switching value acts as setpoint value for the first switch. If, for example, it is established that the battery cell has a voltage which is too low, the first switch can remain open, and the battery cell can remain disconnected from the input and output. If, however, the measured value corresponds to a setpoint value or a setpoint range, the battery cell can be reconnected to the input and output after the measurement by virtue of the first switch being closed.

Furthermore, provision can be made for the measurement means and/or the evaluation means to be fixedly connected to the battery cell unit and/or the battery cell, with the result that they can be removed together. This provides the advantage that the battery cell units or battery cells are easy to replace.

It may be advantageous that the method additionally has the following steps:
A second switch, which is arranged between the input and the output in parallel with the battery cell, can be provided.
In a further step, the second switch can be closed, as a result of which the input is short-circuited with the output.

In other words, provision can be made for a further current path to be provided in parallel with the at least one battery cell, in particular plurality of battery cells, which further current path can both be interrupted and short-circuited by a second switch. This provides the advantage that the at least one battery cell, in particular plurality of battery cells, can be bypassed. In particular when the battery cell unit is connected to further battery cell units via the input and/or output, the battery cells of a battery cell unit can thus be bypassed by closing of the second switch. Closing of the second switch can take place precisely at the time at which the first switch is opened. This provides the advantage that the determination of a measured variable can take place at the disconnected at least one, in particular plurality of battery cells, and the input is in this case not electrically disconnected from the output. As a result, further electrical elements which are connected to the input and/or output can continue to be used during the determination of the measured variable and, if appropriate, can compensate for the failure of the cell being measured at that time. If two switches are provided, the switching value can comprise a setpoint value for both switches.

Furthermore, provision can be made for at least one measured variable to be stored. This provides the advantage that more reliable evaluation of the data is enabled. Provision can be made for a store to be provided for storing the measured variable, which store can be connected in particular to a measurement or evaluation unit. Provision can also be made for the store to be part of the measurement and/or evaluation unit. Provision can furthermore be made for the store to be arranged at the battery cell unit in such a way that said store can be inserted into a battery system or removed from a battery system as a common unit. This provides the advantage that data on the at least one, in particular plurality of battery cells can be stored over their entire life and can be reused by the battery cell itself. This provides the possibility that, for example, when the battery cell no longer has the required properties for a specific application, for example as use in an aircraft, it is disassembled, and another apparatus can be installed which has less stringent demands.

Furthermore, provision can be made for at least one switching value to be determined from stored measured variables by an evaluation unit. In this case, provision can be made for the data to be provided in a store, which can be arranged within the battery cell unit in such a way that said battery cell unit together with the store is replaceable. Provision can be made for the store to also contain data from other battery cells, which may not be part of the battery cell unit. In this case, the setpoint value with which the measured variable is compared in order to determine the switching value can be adapted in such a way that the functionality of the system as a whole remains ensured. Signal means can be provided which signal a recommendation for replacement of the cell when the setpoint value is exceeded or undershot. This provides the advantage that only those cells which deviate from the threshold value adapted to the application and therefore cannot continue to be used are replaced instead of a plurality of battery cells.

Provision can be made for the at least one measured variable to comprise at least one of the following variables and/or for at least one of the following variables to be used for calculating the switching value:
the voltage of the battery cell, in particular as a function of time,
the charging current of the battery cell, in particular as a function of time,
the temperature of the battery cell, in particular as a function of time,
the electrical capacity of the battery cell, in particular as a function of time,
the impedance of the battery cell, in particular as a function of time.

In this case, provision can be made for the measured variables to be determined by at least one measurement means. Both individual and a plurality of measured variables can be determined, wherein, in order to calculate the switching value, both individual and a plurality of or a combination of a plurality of measured variables can be used for calculating the switching value. In particular by virtue of disconnecting the at least one or in particular plurality of battery cells from the input and output, particularly accurate determination of the measured variables is made possible.

A further subject of the invention is a battery cell unit, in particular for a mobile energy supply, having at least one battery cell, an input, which is connected to the at least one battery cell at a first terminal, and an output, which is connected to the at least one battery cell at a second terminal. Furthermore, the battery cell unit has a first switch, which is suitable for connecting the input to the at least one battery cell or disconnecting the input from the at least one battery cell. Furthermore, the battery cell unit has at least one measurement means, which is suitable for determining at least one measured variable and is connected to the battery cell. The battery cell unit furthermore has an evaluation unit, which is connected to the at least one measurement means and is suitable for evaluating the at least one measured variable determined by the at least one measurement means and for calculating at least one switching value, which has a functional relationship with respect to the at least one measured variable. The battery cell unit can in particular be used for a mobile energy supply, for example for an aircraft, motor vehicle, rail-mounted vehicle, or other movable consumers.

The battery cell unit provides the advantage that the battery cell unit can be switched off and on, depending on the measured value determined. In the case of a determined measured value which does not reach a setpoint value or setpoint range, the battery cell is therefore switched off by virtue of the first switch not being closed again. If, however, the measured variable does reach the setpoint value or setpoint range, the first switch is closed again and the battery cell remains switched on. The opening of the first switch can take place at specific intervals which are adapted in particular to the measured variable to be determined. This provides the advantage that the disconnection of the battery cell can take place as rarely as possible, and the performance of the battery cell unit is increased alongside increased operational safety.

The input and the output are each connectable to a first and second electrical element, wherein this electrical element may be, for example, a further battery cell unit, an electrical circuit, a consumer or a connecting element, in particular in the form of a male connector or a female connector. This provides the advantage that the battery cell unit can be integrated in a battery system.

Instead of a single battery cell, it is also possible for a plurality of battery cells to be connected both in parallel and in series. In this case, in the case of a series circuit, in each case only one battery cell is connected to the input and a further battery cell is connected to the output, and, in the case of a parallel circuit, if appropriate, a plurality of battery cells is connected to the input and to the output. The use of a plurality of battery cells provides the advantage that the voltage or the current can be increased.

The first switch, in the closed state, connects the first terminal of the battery cell to the input and, in the open state, disconnects this connection. In this case, the connection between the input and the first terminal of the battery cell can take place directly via the switch and via one or more cell lines. In this case, the switch itself can be in the form of a relay, which provides the advantage of DC isolation which is particularly safe. As an alternative, provision can also be made for the switch to be based on a semiconductor, as a result of which a high number of switching cycles can be enabled. Likewise, the switch can also be in the form of a MOSFET or IGFET, which can be designed to be particularly small and favorable.

The measured variable which is determined by the battery cell disconnected from the input may be any measurable variable, in particular temperature, pressure, concentration or electrical variables, such as, for example, voltage, current or impedance. The measured variables are detected by measurement means, wherein corresponding accesses to the battery cell unit are provided. In order to measure electrical variables, further terminals can be provided at the at least one battery cell, in particular at a plurality of battery cells. Thus, a means for measuring the impedance can be connected to at least one or in particular a plurality of battery cells in order to measure the impedance at the time at which the first switch is open and the battery cell or battery cells are deenergized. This provides the advantage that, in this way, the impedance can be determined with particular accuracy, which enables improved description of the state of the cell.

During the evaluation of the measured variable, a switching value is determined on the basis of the measured variable. If a plurality of switches is provided, the switching value can also contain a respectively adapted setpoint value for all of the switches. In this case, the switching value can have a logic value which can act as setpoint value for a switch. For example, a switching value of 1 would correspond to a closed switch, and a switching value of 0 would correspond to an open switch. During the evaluation of the measured variable by the evaluation unit, the measured variable can be compared with a setpoint variable or setpoint range. This setpoint value may be, for example, a universally valid setpoint value, for example a cell voltage, which should not be undershot. This provides the advantage that, irrespective of the state differences of the battery cells which may be present, switching values of the first switch can be determined. As an alternative to this or in addition, it is also possible for the measured variable to be compared with a setpoint value, which has been individually adapted to the battery cell. Thus, it may arise that battery cells are subject to certain manufacturing-dependent fluctuations. Thus, a cell which has a low voltage from the beginning of production on, but, for this, has an increased capacity, for example, can obtain a correspondingly adapted setpoint value.

For the evaluation, an evaluation unit is provided, which may be in the form of a microcontroller. Microcontrollers provide the advantage that they can be designed to be particularly small and favorable. Furthermore, provision can be made for the evaluation unit to be in the form of an FPGA, which can be adapted particularly easily to measurement tasks. As an alternative or in addition to this, the evaluation unit can also be in the form of an ASIC, which can be produced particularly favorably in large production numbers.

The determined switching value acts as setpoint value for the first switch. If, for example, it is established that the battery cell has a voltage which is too low, the first switch can remain open, and the battery cell can remain disconnected from the input and output. If, however, the measured value corresponds to a setpoint value or a setpoint range, the battery cell can be reconnected to the input and output after the measurement by virtue of the first switch being closed.

Furthermore, provision can be made for the measurement means and/or the evaluation means to be fixedly connected to the battery cell unit and/or the battery cell, with the result that they can be removed together. This provides the advantage that the battery cell units or battery cells are easy to replace.

Furthermore, provision can be made for a second switch to be provided, which is arranged between the input and the output, in parallel with the battery cell. In other words, during the disconnection of the battery cell from the circuit by opening of the first switch, the current can thus be conducted on in parallel with the battery cell from the input to the output, or vice versa. This provides the advantage that, despite the disconnection of the at least one, in particular plurality of battery cells, conducting-on from the input to the output or vice versa is ensured.

A further subject of the invention is a battery system, having a plurality of battery cell units, which are connected in series and/or in parallel with one another. In this case, provision can be made for the at least one measurement means to be connected to a plurality of battery cell units and to be suitable for determining at least one measured variable. This provides the advantage that individual measurement means do not need to be provided for each battery cell unit, with the result that cost savings can be made. Furthermore, provision can be made for an evaluation unit to be connected to a plurality of measurement means and to be suitable for evaluating the measured variables determined by the measurement means and for calculating at least one switching value, which has a functional relationship with respect to the measured variables. This also provides the advantage that fewer evaluation units are necessary than when each measurement means has a dedicated evaluation unit.

As an alternative to this, however, provision may also be made for the battery cell units in the battery system to each have dedicated measurement means and evaluation units, with the result that the battery cell units can be removed from the battery system or inserted without the functionality of the battery system being disrupted. In particular, provision may be made for battery cell units to be removed from a battery system with increased demands and to be installed in a battery system with lower demands when it is established by the evaluation unit that the increased demands are no longer met by the battery cell unit.

A further subject of the invention is the use of the method for monitoring and controlling the battery system. In this case, furthermore, the following steps can be provided:
opening of at least one first switch, as a result of which at least one battery cell is interrupted from the input,
closing of at least one second switch, as a result of which the input is short-circuited with the output,
determination of a measured variable of at least one battery cell by the at least one measurement means,
evaluation of the measured variable by the evaluation unit, wherein at least one switching value is determined on the basis of the measured variable,
adaptation of the switching state of at least one first switch, on the basis of the at least one switching value,
adaptation of the switching state of at least one second switch, on the basis of the at least one switching value,

for monitoring and controlling the battery system. In this case, provision can be made for the first switch to be opened at defined time intervals in order to perform deenergized measurement of the battery cell, and for the second switch to be closed during the measurement in order to thus bypass the battery unit and ensure the functionality of the battery system.

Within the system, provision can be made for the measurements to be temporally matched to one another in such a way that only ever one or at least a few battery cells are measured at the same time, with the result that the functionality of the battery system is overall ensured.

Likewise, provision can be made for particularly suitable battery units to be used, on the basis of the presently required demand on the battery system, by virtue of closing of the first switch and opening of the second switch for the provision of power and rather unsuitable battery cell units to be ruled out from use by virtue of opening of the first switch and closing of the second switch. This may be the case, for example, when, during acceleration of a vehicle, a particularly high power is intended to be output by the battery cell units, for which purpose a few battery cell units may possibly be unsuitable. However, these battery cell units can quite easily still have a high capacity, which can be used, for example, in phases when there is a lower demand for the power output.

Furthermore, provision can be made for the discrepancy of a battery cell unit in comparison with a further battery cell unit to be included in the calculation of the switching value by the evaluation unit. In other words, the evaluation unit can compare the status of the individual battery cell units with one another and decide which of the battery cell units are required for the present demands and are best suited for this. Correspondingly, the switching state of the first two switches of the battery cell units can be adapted in such a way that the battery cells of the battery cell units are either connected to the respective inputs and outputs or else disconnected therefrom.

Further features and details of the invention result from the dependent claims, the description and the drawings. In this case, features and details which have been described in connection with the method according to the invention of course also apply in connection with the battery cell unit according to the invention, the battery cell system according to the invention and/or the use according to the invention, and respectively vice versa, with the result that, with respect to the disclosure relating to the individual aspects of the invention, reciprocal reference always is or can be made.

### BRIEF DESCRIPTION OF THE DRAWINGS

Further measures improving the invention result from the description below relating to a few exemplary embodiments of the invention, which are illustrated schematically in the figures. All of the features and/or advantages described in the claims, the description or the drawings, including structural details, physical arrangements and method steps, may be essential to the invention both per se and in the various combinations. It should be noted here that the figures only have a descriptive character and are not intended to restrict the invention in any way. In the drawings:

FIG. 1 shows a schematic view of a battery cell unit in various switching states,

FIG. 2 shows a further schematic illustration of the battery cell unit,

FIG. 3 shows a schematic illustration of the battery system,

FIG. 4 shows a process diagram of a method according to the invention.

In the following figures, identical reference symbols are used for the same technical features even of different exemplary embodiments.

### DETAILED DESCRIPTION

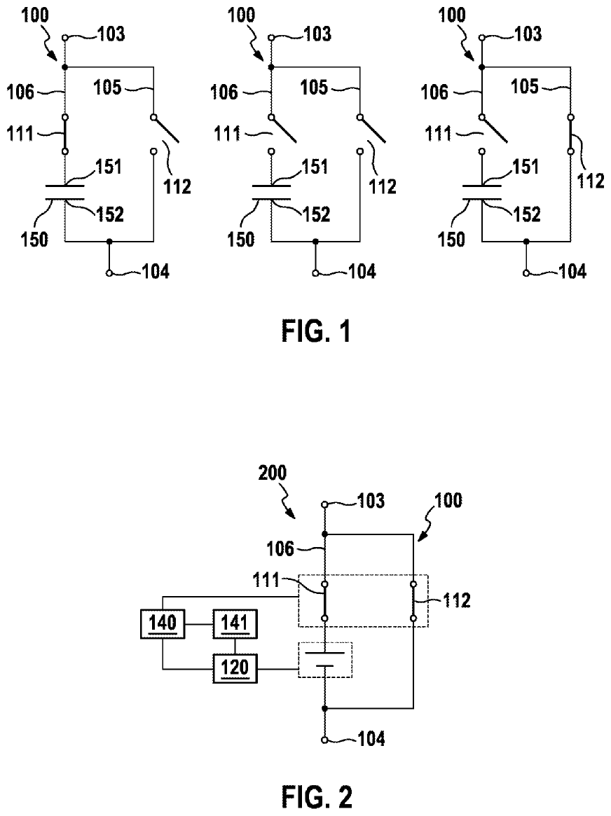

FIG. 1 shows, on the left-hand side, a battery cell unit 100 with an input 103 and an output 104. The input 103 is connected to a battery cell 150 at a first terminal of the battery cell 151 via a first switch 111. The current path between the input 103 via the switch 111 and the battery cell 150 to the output 104 is referred to below as cell line 106. Via this cell line 106, the current can be conducted via the battery cell 150 from the input 103 to the output 104, or vice versa. In parallel with this, a second current path 105 is shown, which likewise connects the input 103 to the output 104 via a second switch 112. In the state illustrated on the left in FIG. 1, the battery cell 150 is connected to the input 103 and the output 104. In this case, for example, a consumer can be provided between the input 103 and the output 104, which consumer can be operated by the output power of the battery cell 150. As an alternative to this, it is likewise conceivable for further battery cell units to be provided connected in series or parallel at the input 103 and/or output 104, as a result of which a battery system 1000 is produced. In order that the current can flow from the battery cell 150 into the battery system 1000 or to the consumer, in addition a switch 112 which may be present needs to be open. This is shown in the left-hand and central illustration in FIG. 1.

During determination of a measured variable of the battery cell 150, the first switch 111 is opened, wherein the second switch 112 can be closed. As a result, the battery cell unit 150 is deenergized, which enables more precise determination of the measured variable. This procedure is illustrated on the right-hand side in FIG. 1.

FIG. 2 shows a further view of the battery cell unit 100, in which, furthermore, measurement means 120 and an evaluation unit 140 with a store 141 are illustrated schematically. The measurement means 120 serve the purpose of determining a measured variable of the battery cell 150. The measurement means 120 are connected to the evaluation unit 140, which evaluates the measured values and, on the basis thereof, determines a switching value, which determines at least the switching state of the first switch 111 or the switching state of the first and the second switches 111, 112. The evaluation unit 140 can in this case use values which are either detected directly by the measurement means 120 or are stored in a store 141. The evaluation unit 140 can adapt the switching state of the first and/or second switches 111, 112 to the setpoint value.

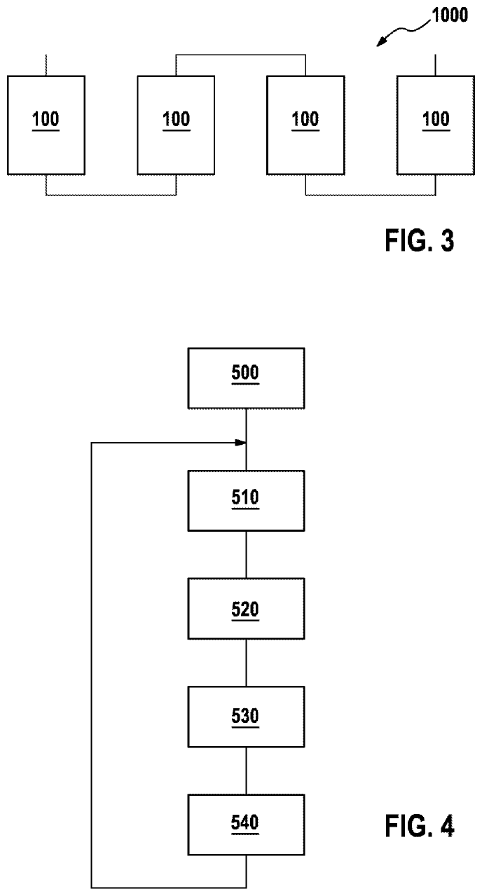

FIG. 3 illustrates a battery system 1000, in which the battery cell units 100 are illustrated as being connected in series. Of course, the individual battery cell units can also be connected in parallel and/or in series. This provides the advantage that the voltage or the current intensity can be increased.

FIG. 4 illustrates a flowchart which shows, by way of example, a configuration of a method according to the invention. In a first method step 500, first the battery cell units 100, first switch 111, in particular second switch 112, measurement means 120 and an evaluation unit 140 are provided. In a next step 510, which can be repeated at defined time intervals, the first switch 111 is opened, and the second switch 112 is closed. In the subsequent step 520, the measurement means 120 detect at least one measured value. This measured value is evaluated in the subsequent step 530 by the evaluation unit 140, which calculates, on the basis of the at least one measured value, a switching value for the first switch 111, in particular the second switch 112. In the next step 540, the switching state of the first switch 111, in particular the second switch 112, is adapted corresponding to the switching value. This means that the battery cell 150 is either reset to its initial state or else remains disconnected from the input 103 and output 104.

The explanation above of the embodiments describes the present invention exclusively using examples. It is of course possible for individual features of the embodiments, if technically feasible, to be combined freely with one another without departing from the scope of the present invention.

1. A method for monitoring and controlling a battery cell unit (100), the method comprising the following steps:
providing at least one battery cell (150), the battery cell (150) having
a first terminal (151) connected to an input (103), the input (103) connectable to a first electrical element, and
a second terminal (152) connected to an output (104), the output connectable to a second electrical element,
providing a first switch (111) configured to connect and disconnect the first terminal (151) to the input (103),
opening the first switch (111), for disconnecting the connection between the input (103) and the first terminal (151),
determining a measured variable of the at least one battery cell (150) disconnected from the input (103),
evaluating the measured variable, wherein at least one switching value is determined on the basis of the measured variable, and
adapting the switching state of the first switch (111) on the basis of the at least one switching value, for controlling and monitoring the battery cell unit (100).

2. The method as claimed in claim 1,
wherein the method additionally has the following steps:
providing a second switch (112), which is arranged between the input (103) and the output (104) in parallel with the at least one battery cell (150),
closing the second switch (112), as a result of which the input (103) is short-circuited with the output (104).

3. The method as claimed in claim 1,
wherein the at least one measured variable is stored.

4. The method as claimed in claim 3,
wherein at least one switching value is determined from stored measured variables by an evaluation unit (130).

5. The method as claimed in claim 1,
wherein the at least one measured variable comprises at least one of the following variables and/or at least one of the following variables is used for calculating the switching value:
voltage of the battery cell (150),
charging current of the battery cell (150),
temperature of the battery cell (150),
electrical capacity of the battery cell (150),
impedance of the battery cell (150).

6. A battery cell unit (100), comprising:
at least one battery cell (150),
an input (103), which is connected to the at least one battery cell (150) at a first terminal (151),
an output (104), which is connected to the at least one battery cell (150) at a second terminal (152),
a first switch (111), configured to connect and disconnect the input (103) to the at least one battery cell (150),
at least one measurement means (120), which is connected to the at least one battery cell (150) and configured to determine at least one measured variable,
and an evaluation unit (140), which is connected to the at least one measurement means (120) and configured to evaluate the at least one measured variable determined by the at least one measurement means (120) and to calculate at least one switching value, which has a functional relationship with respect to the at least one measured variable.

7. The battery cell unit (100) as claimed in claim 6,
wherein a second switch (112) is provided, which is arranged between the input (103) and the output (104), in parallel with the battery cell (150).

8. A battery system (1000), having a plurality of battery cell units (100) as claimed in claim 6.

9. (canceled)

10. (canceled)
